(19) United States
(12) Patent Application Publication
(10) Pub. No.: US 2024/0188421 A1
(43) Pub. Date: Jun. 6, 2024

(54) ORGANIC-INORGANIC HOLE TRANSPORT BILAYER FOR CARBON ELECTRODE PEROVSKITE SOLAR CELLS AND CARBON ELECTRODE PEROVSKITE SOLAR CELLS WITH ORGANIC-INORGANIC HOLE TRANSPORT BILAYER

(71) Applicants: Henan University, Kaifeng (CN); Solaires Entreprises Inc., Victoria (CA)

(72) Inventors: Furui TAN, Kaifeng (CN); Yaqing LI, Kaifeng (CN); Wanlong WANG, Kaifeng (CN); Chen DONG, Kaifeng (CN)

(73) Assignees: Henan University, Kaifeng (CN); Solaires Entreprises Inc., Victoria (CA)

(21) Appl. No.: 18/517,176

(22) Filed: Nov. 22, 2023

(30) Foreign Application Priority Data
Dec. 5, 2022 (CA) 3184079

(51) Int. Cl. H10K 85/50; H10K 30/86; H10K 71/12; H10K 71/40; H10K 85/10

(52) U.S. Cl. CPC H10K 85/50; H10K 85/113; H10K 30/86; H10K 71/12; H10K 71/40

(57) ABSTRACT

A solar cell is provided that comprises: a glass substrate or a plastic polymeric substrate; a first electrode disposed on the glass substrate or the plastic polymeric substrate, an electron transport layer disposed on the first electrode; a perovskite layer disposed on the electron transport layer; an organic-inorganic hole transport bilayer comprising an organic layer which is disposed on the perovskite layer and an inorganic layer which is disposed on the organic layer; and a second electrode disposed on the inorganic layer.

### CROSS REFERENCE TO RELATED APPLICATIONS

This application claims priority to Canadian Patent Application Serial No. 3,184,079, filed Dec. 5, 2022, entitled ORGANIC-INORGANIC HOLE TRANSPORT BILAYER FOR CARBON ELECTRODE PEROVSKITE SOLAR CELLS AND CARBON ELECTRODE PEROVSKITE SOLAR CELLS WITH ORGANIC-INORGANIC HOLE TRANSPORT BILAYER. The above-identified priority patent application is incorporated herein by reference in its entirety.

### FIELD

The present technology is a carbon electrode perovskite solar cell that has improved efficiency and longevity. More specifically, it is a carbon electrode perovskite solar cell with a hole-transport bilayer in which one layer is a discrete organic layer and the other layer is a discrete inorganic layer.

### BACKGROUND

There are numerous perovskite solar cells that include a hybrid organic-inorganic layer. For example, U.S. patent Ser. No. 10/403,708 discloses systems, methods, and apparatus related to solar cells. In one aspect a solar cell includes a first electrode, a hole transport layer disposed on the first electrode, a first perovskite layer disposed on the hole transport layer, a cationic diffusion barrier disposed on the first perovskite layer, a second perovskite layer disposed on the cationic diffusion barrier, an electron transport layer disposed on the second perovskite layer, and a second electrode disposed on the electron transport layer. The first perovskite layer comprises a different perovskite than the second perovskite layer. This technology includes two perovskite layers which are composed of an organic-inorganic compound and not an organic layer and an inorganic layer.

United States Patent Application Publication No. 20200294727 discloses an organic-inorganic hybrid material applicable to a perovskite solar cell having a first electrode, an electron transport compound layer arranged on the first electrode, a perovskite compound layer arranged on the electron transport compound layer, a hole transport layer arranged on the perovskite compound layer, and a second electrode arranged on the hole transport layer, the organic-inorganic hybrid material comprising a compound represented by “KₓA1_{y}A2_{z}PbX1ₚX2_{q}”. Wherein, K represents potassium, Pb represents lead, A1 and A2 represent freely selectable cations, which may be organic or inorganic, and may be same; X1 and X2 represent halogen atoms, which may be same; x represents a numerical value ranging from 0.01 to 0.20; and y, z, p and q represent freely selectable numerical values which satisfy x+y+z=1 and p+q=3. This technology includes a hybrid material composed of an organic-inorganic compound and not an organic layer and an inorganic layer.

United States Patent Application 20180040840 discloses a flexible solar cell including a photoelectric conversion layer that contains an organic-inorganic perovskite compound and being excellent in light resistance and photoelectric conversion efficiency. The present invention relates to a flexible solar cell having a structure including: a metal foil; an electron transport layer; a photoelectric conversion layer; a hole transport layer; and a transparent electrode stacked in the stated order, the photoelectric conversion layer containing an organic-inorganic perovskite compound represented by the formula: R-M-X₃ where R represents an organic molecule, M represents a metal atom, and X represents a halogen atom or a chalcogen atom. This technology includes an organic-inorganic perovskite compound and not an organic layer and an inorganic layer.

United States Patent Application Publication No. 20200013974 discloses a solar cell having high durability against deterioration due to moisture ingress from the side surfaces. The solar cell 10 of the present invention includes: first and second electrodes 12 and 17; a perovskite layer 14 provided between the first and second electrodes 12 and 17 and containing an organic-inorganic perovskite compound (A) represented by the formula RMX₃ where R is an organic molecule, M is a metal atom, and X is a halogen atom; and a side-surface-protecting layer 15 provided on a peripheral side of the perovskite layer 14 to coat at least part of a side surface of the perovskite layer 14, the side-surface-protecting layer 15 containing at least one selected from the group consisting of a metal halide (B1) and an organometal halide (B2) or containing an organohalide (C). This technology includes an organic-inorganic perovskite compound and not an organic layer and an inorganic layer.

CN109768167 discloses a double-layer hole transport layer formed by sequentially stacking an inorganic hole transport layer thin film and an organic hole transport layer thin film is used to replace a conventional single-layer organic hole transport layer or an inorganic hole transport layer, which can significantly reduce the current hysteresis effect of a battery. In the present invention, a single organic PEDOT: PSS hole transport layer is used, and the battery hysteresis factor thereof is 0.141; a single inorganic NiO_{X} hole transport layer is used, and the battery hysteresis factor thereof is 0.177 After the inorganic/organic double-layer hole transport layer constructed using NiO_{X} PEDOT: PSS, the current hysteresis effect of the perovskite solar cell is essentially eliminated. This technology does not employ a carbon electrode.

United States Patent Application Publication No. 20200350125 discloses an organic-inorganic hybrid solar cell and method for manufacturing the same wherein the solar cell includes a first electrode, a first common layer provided on the first electrode, a light absorption layer including a perovskite material provided on the first common layer, a second common layer provided on the light absorption layer, and a conductive adhesive layer provided on the second common layer. In an exemplary embodiment of the present specification, the forming of the light absorption layer includes coating each of a solution including an organic halide and a solution including a metal halide on an upper portion of the first common layer or coating a solution including both an organic halide and a metal halide on an upper portion of the first common layer. There is no disclosure indicating that the organic and inorganic solutions are coated as discrete layers. The fact that the solution can include both the organic and inorganic halides suggests there are not discrete layers.

What is needed is a perovskite solar cell that includes a carbon electrode. It would be preferably if the perovskite solar cell has hole transport layers that have a low energy loss during charge transfer and are photothermally stable when exposed to the air via mesoporous carbon of the carbon electrode. It would be preferable if the hole transport layers were arranged as an organic-inorganic hole transport bilayer. It would be preferable if there is an improved ohmic contact between the hole transport layers and the carbon electrode. It would be further preferable if there is fast and efficient holes transfer.

### SUMMARY

The present technology is a perovskite solar cell that includes a carbon electrode. The perovskite solar cell has hole transport layers that have a low energy loss during charge transfer and are photothermally stable when exposed to the air via mesoporous carbon of the carbon electrode. The hole transport layers are arranged as an organic-inorganic hole transport bilayer. There is an improved ohmic contact between the hole transport layers and the carbon electrode. There is fast and efficient holes transfer.

In one embodiment a solar cell is provided comprising: a glass substrate or a plastic polymeric substrate; a first electrode disposed on the glass substrate or plastic polymeric substrate; an electron transport layer is disposed on the electrode; a perovskite layer disposed on the electron transport layer; an organic-inorganic hole transport bilayer comprising an organic layer which is disposed on the perovskite layer and an inorganic layer which is disposed on the organic layer; and a second electrode disposed on the inorganic layer.

In the solar cell, the organic layer of the organic-inorganic hole transport bilayer may comprise one of 2,2′,7,7′-tetrakis(N,N-di-p-methoxyphenyl-amine)-9,9′-spirobifluorene, poly(3,4-ethylenedioxythiophene) polystyrene sulfonate, poly[bis(4-phenyl)(2,4,6-trimethylphenyl)amine, poly(N,N′-bis(4-butylphenyl)-N,N′-bis(phenyl)benzidine, and a polythiophene.

In the solar cell, the inorganic layer of the organic-inorganic hole transport bilayer may comprise one of CuX (X═I or S), CuXCN (X═S or Se), MxOy (M═Ni, Mo, V, Co, or Cu), and CuMO₂ (M═Ga, Cr, or Al).

In the solar cell, the organic layer may be a polythiophene layer.

In the solar cell, the inorganic layer may be a nickel oxide layer.

In the solar cell, the nickel oxide may be a nickel oxide-alkyl ammonium bromide layer.

In the solar cell, nickel oxide-alkyl ammonium bromide layer may be a nickel oxide-alkyl ammonium bromide nanoparticle layer.

In the solar cell, the perovskite layer may comprise FA_{0.6}MA_{0.4}PbI₃.

In the solar cell, the FA_{0.6}MA_{0.4}PbI₃ of the perovskite layer may be doped with guanidinium chloride (GdmCl).

In the solar cell, the electron transport layer may be a SnO₂ layer.

In the solar cell, the substrate may be a glass substrate.

In the solar cell, the substrate may be a plastic polymeric substrate.

In the solar cell, the first electrode may be an indium tin oxide electrode.

In another embodiment, a method of fabricating a solar cell is provided, the method comprising: selecting a substrate and first electrode combination, the substrate and first electrode combination comprising one of an indium tin oxide electrode and glass combination or an indium tin oxide electrode and plastic polymeric combination; annealing an electron transport layer onto the indium tin oxide electrode; coating the electron transport layer with a perovskite solution to provide a perovskite layer; annealing the perovskite layer to the electron transport layer; coating the perovskite layer with an organic hole transfer layer; coating the organic hole transfer layer with an inorganic hole transfer layer to provide an organic-inorganic hole transfer bilayer; and coating the inorganic hole transfer layer of the organic-inorganic hole transfer bilayer with a carbon electrode, thereby fabricating the solar cell.

The method may further comprise dissolving guanidinium chloride (GdmCl) into the perovskite solution before coating the electron transport layer with the perovskite solution.

In the method, the inorganic hole transport layer may be synthesized with nickel oxide.

The method may further comprise mixing the nickel oxide with cetyltrimethylammonium bromide prior to synthesize the inorganic hole transport layer.

In the method, the perovskite solution may comprise FA_{0.6}MA_{0.4}PbI₃.

In the method, the organic hole transport layer may be synthesized with a polythiophene.

### BRIEF DESCRIPTION OF THE DRAWINGS

FIG. 1 is a schematic of the solar cell of the present technology.

FIGS. 2A-D show ultraviolet photoelectron spectroscopy spectra of the perovskite, P3HT, NiOₓ and NiOₓ-CTAB on ITO glass film; FIG. 2E shows energy level diagrams of solar cells; FIG. 2F shows photoluminescence (PL) and FIG. 2G shows time-resolved PL (TRPL) spectra of perovskite, perovskite/P3HT, perovskite/P3HT/NiOₓ and perovskite/P3HT/NiOₓ-CTAB films.

FIGS. 3A-H show device performance statistics for the blade-coating solar cells with different HTL: FIG. 3A shows performance statistics with open circuit voltage; FIG. 3B shows performance statistics for fill factor (FF); FIG. 3C shows short-circuit current density; FIG. 3D shows efficiency; FIG. 3E shows best J-V curves under reverse and forward scanning of the best-performing solar cells for P3HT, P3HT/NiOₓ and P3HT/NiOₓ-CTAB; FIG. 3F shows Quantum Efficiency (EQE) and integrated Jsc of the devices with P3HT, P3HT/NiOₓ and P3HT/NiOₓ-CTAB; FIG. 3G shows dark current density versus voltage with different HTLs and FIG. 3H shows best J-V curves of the best-performing solar cells for P3HT, P3HT-NiOₓ and P3HT/NiOₓ in the same batch.

FIG. 4A shows transient photovoltage decay; FIG. 4B shows the dependence of V_{oc} on light intensity; FIG. 4C shows bias voltage dependence of R_{ct} abstracted from the Nyquist plots of the three cells electrochemical impedance spectra; FIG. 4D shows the I-V properties of different NiOx sandwiched between ITO and carbon; FIG. 4E shows transient photocurrent decay (TPC); and FIG. 4F shows J1/2-V curves of SCLC used to calculate the hole mobility.

FIG. 5A shows XRD patterns with different pristine HTLs; and FIG. 5B shows XRD patterns with different HTLS aged under ambient conditions (at room temperature and 40% humidity) for 15 days.

### DESCRIPTION

Except as otherwise expressly provided, the following rules of interpretation apply to this specification (written description and claims): (a) all words used herein shall be construed to be of such gender or number (singular or plural) as the circumstances require; (b) the singular terms “a”, “an”, and “the”, as used in the specification and the appended claims include plural references unless the context clearly dictates otherwise; (c) the antecedent term “about” applied to a recited range or value denotes an approximation within the deviation in the range or value known or expected in the art from the measurements method; (d) the words “herein”, “hereby”, “hereof”, “hereto”, “hereinbefore”, and “hereinafter”, and words of similar import, refer to this specification in its entirety and not to any particular paragraph, claim or other subdivision, unless otherwise specified; (c) descriptive headings are for convenience only and shall not control or affect the meaning or construction of any part of the specification; and (f) “or” and “any” are not exclusive and “include” and “including” are not limiting. Further, the terms “comprising.” “having.” “including.” and “containing” are to be construed as open-ended terms (i.e., meaning “including, but not limited to,”) unless otherwise noted.

Recitation of ranges of values herein are merely intended to serve as a shorthand method of referring individually to each separate value falling within the range, unless otherwise indicated herein, and each separate value is incorporated into the specification as if it were individually recited herein. Where a specific range of values is provided, it is understood that each intervening value, to the tenth of the unit of the lower limit unless the context clearly dictates otherwise, between the upper and lower limit of that range and any other stated or intervening value in that stated range, is included therein. All smaller sub ranges are also included. The upper and lower limits of these smaller ranges are also included therein, subject to any specifically excluded limit in the stated range.

Unless defined otherwise, all technical and scientific terms used herein have the same meaning as commonly understood by one of ordinary skill in the relevant art. Although any methods and materials similar or equivalent to those described herein can also be used, the acceptable methods and materials are now described.

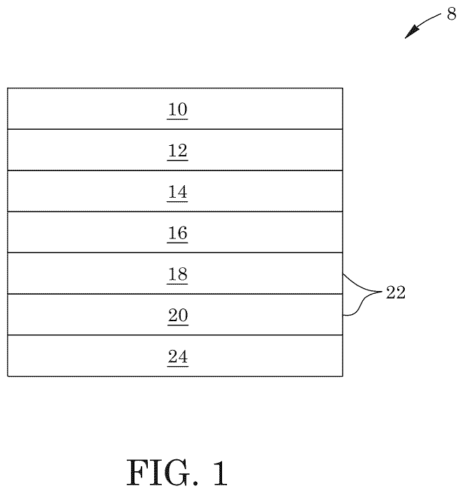

A perovskite solar cell, generally referred to as 8 is shown in FIG. 1. The solar cell 8 includes, in order, a glass substrate 10, an indium tin oxide electrode 12 to which an electron transport layer 14 of SnO₂ is annealed. Above that is a perovskite layer 16, then a first hole transfer layer 18 which is a polythiophene (the organic layer) and a second hole transfer layer 20 which is nickel oxide-alkyl ammonium bromide (the inorganic layer). The hole transfer layers 18, 20 are collectively referred to as an organic-inorganic hole transfer bilayer 22. This hole transfer bilayer 22 is between the perovskite layer 16 and a carbon electrode 24. In an alternative embodiment, the substrate 10 is a plastic polymer, providing for a flexible perovskite solar cell. In alternative embodiments, the organic layer, is for example, but not limited to, one of 2,2′,7,7′-tetrakis(N,N-di-p-methoxyphenyl-amine)-9,9′-spirobifluorene (Spiro-OMeTAD), PEDOT:PSS, poly[bis(4-phenyl)(2,4,6-trimethylphenyl)amine, poly(N,N′-bis(4-butylphenyl)-N,N′-bis(phenyl)benzidine), and poly(3-hexylthiophene-2.5-diyl) and the inorganic layer is, for example, but not limited to, one of CuX (X═I or S), CuXCN (X═S or Sc), MxOy (M═Ni, Mo, V, Co, or Cu), and CuMO₂ (M═Ga, Cr, or Al).

The perovskite solar cell was fabricated using indium tin oxide (ITO) glass substrate and electrode combination (purchased from Shangyang Technology). ITO glass combination (4×6.7 cm²) were sequentially ultrasonic cleaned by detergent, deionized water, ethanol, acetone, and isopropanol, successively, each step lasted for 30 min and finally dried with nitrogen gas. The combination was thoroughly cleaned and treated with plasma for 500 seconds, 70% power before usage. SnO₂ was deposited on the pre-cleaned ITO glass substrate (combination) as an electron transport layer (ETL). It was prepared by spinning SnO₂ solution (tin oxide, 15% in H₂O colloidal dispersion liquid, diluted by deionized water with a volume ratio of 1:4) at 4000 rpm for 30s, then the substrates (combinations) were annealed at 150° C. for 30 min in ambient air. After cooling down to room temperature, the ITO/SnO₂ substrates were further treated with UV-ozone radiation for 150 seconds. Then a layer of potassium chloride (KCl) was spin-coated onto SnO₂ layer at 3000 rpm for 30 seconds and annealed at 100° C. for 10 min in air. The concentration of KCl solution is 10 mM deionized aqueous solution. In an alternative embodiment the combination is ITO-plastic polymeric material, for example, but not limited ITO Polyethylene terephthalate.

The FA_{0.6}MA_{0.4}PbI₃ perovskite solution, also called precursor solution, with a concentration of 1M (doped with 5% mole ratio guanidinium chloride (GdmCl)) was prepared by dissolving GdmCl (4.94 mg), Formamidinium iodide (107.3 mg), methylammonium iodide (MAI) (65.86 mg) and PbI₂ (479.44 mg) in a mixed solution of 1.04 mL of 2-2-Methoxyethanol and N-Methyl-2-pyrrolidone (NMP) (v/v, 25:1) and then the mixture was stirred for 3 hours. The precursor solution was filtered using 0.22 μm polytetrafluoroethylene filters. For the fabrication of compact perovskite films on ITO/SnO₂/KCl substrates, a typical blade coating method was used. The coating machine was set at the base temperature of 30° C., and the coating speed was 5 mm/sec. 70 μm thick adhesive tape was stuck on the side of the substrate coated with SnO₂ and KCl. 85 μL of the precursor solution was uniformly dropped into the gap of the tablet and coating began with concomitant blowing of the wet film back and forth for 5-10 seconds with nitrogen. Next, the isopropyl alcohol solution of 5 mg/mL methylammonium chloride (MACI) was dynamically spun on the blow-dried film at a rotational speed of 4500 rpm for 30 seconds. Immediately after finishing the coating, the substrate was annealed in air at 110° C. for 10 minutes.

The coated perovskite film was dynamically rotated with 10 mg/mL polythiophene hole transfer (P3HT) chlorobenzene solution at 3000 rpm for 30 seconds. After finishing the rotary coating, it was placed on a 110° C. hot table and annealed for 5 minutes. This process of P3HT spin coating was carried out in a glovebox.

The isopropyl alcohol dispersion of a nickel oxide-alkyl ammonium bromide, which in one embodiment is nickel oxide-cetyltrimethylammonium bromide (NiOₓ-CTAB) (2%) was dynamically spun on the ITO/SnO₂/PVK/P3HT coated film at 3500 rpm for 30 seconds. After finishing the rotary coating, it was annealed in air for 5 minutes at 60° C. The carbon paste was applied to the top of the shadow-mask covered NiOₓ-CTAB to form a carbon electrode by blade coating. After removing the shadow mask, the substrate was divided into many subcells and annealed in ambient air at 110° C. for 30 minutes.

Through adding an alkyl ammonium bromide (CTAB) modified nickel oxide (NiOx) nanoparticle layer on polythiophene (P3HT) layer, the bilayer HTL achieves a cascade type-II energy level alignment at the perovskite/HTL interfaces and a preferential ohmic contact at NiOx/carbon electrode, which greatly benefits an enhanced charge collection and depressed charge transfer recombination. Compared with the single P3HT layer, the planar composite enables a robust interfacial contacts by protecting perovskite from being corroded by carbon paste during fabrication. As a result, the blade-coated FA_{0.6}MA_{0.4}PbI₃ perovskite solar cells (fabricated in ambient air in a fume hood) with a carbon electrode deliver a high efficiency of at least 20.2% and withstood over 200 hours maximum power point (MPP) tracking in air without encapsulation (80% efficiency retained).

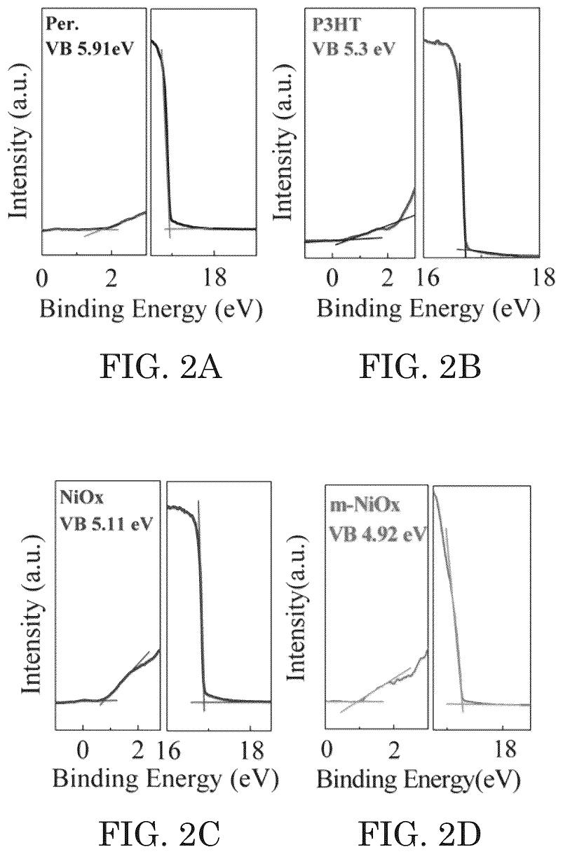

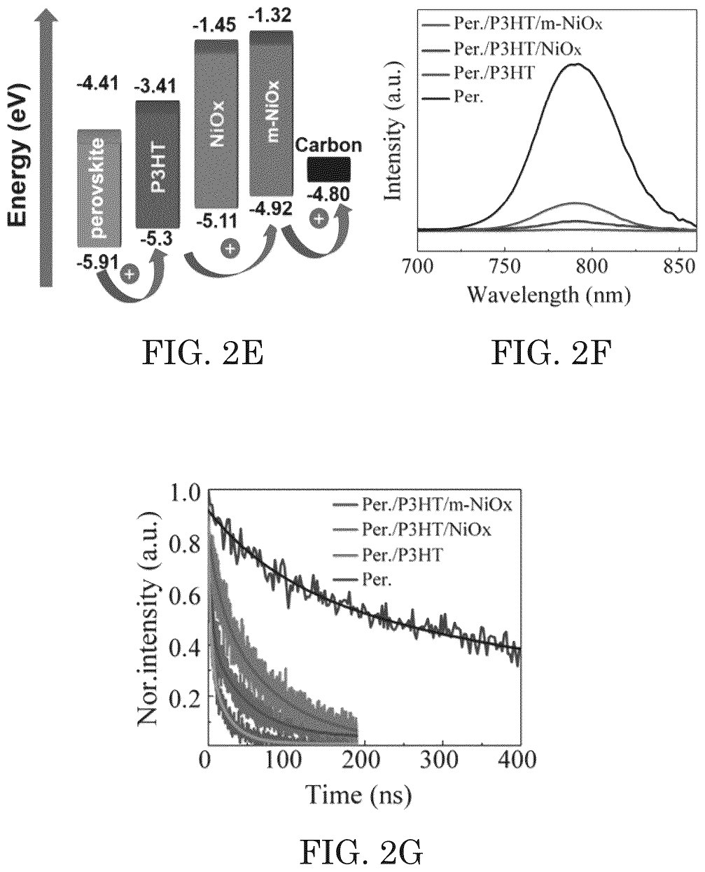

Ultraviolet photoelectron spectroscopy (UPS,) was used to measure valence band energy level (VB) of each layer (FIG. 2A-D). It can be calculated that the VB of the P3HT (−5.3 eV) is lower than that of the NiOₓ film (−5.11 eV) and the NiOₓ-CTAB film (−4.87 eV), which matches well with the VB of the perovskite layer (−5.91 eV). From the light absorption spectra that show the optical bandgap of each material, the entire energy level alignments are shown in FIG. 2E. A cascade type-II alignment is formed at the perovskite/P3HT/NiOx (or NiOx-CTAB) interfaces, indicative of efficient holes collection from perovskite to P3HT and then to NiOx. CTAB modification to NiOx makes its VB level shallower, providing a stronger driving force for holes extraction.

The kinetics of charge transfer at the HTL/perovskite interfaces was examined by photoluminescence (PL) and time-resolved PL (TRPL) techniques. FIG. 2F shows the steady state PL spectra of the glass/perovskite, glass/perovskite/P3HT and glass/perovskite/P3HT/NiOₓ (or NiOₓ-CTAB) films. The PL spectra show the same peak location at around 790 nm. The PL intensity of perovskite with P3HT/NiOₓ HT bilayer was much lower than that of the perovskite films with the only P3HT while CTAB modified NiOx on P3HT further decreased the PL intensity. These results indicate that adding NiOx on P3HT would drive a more effective hole extraction from the perovskite because of the type-II valence band offset at the interface, especially when using the CTAB modified NiOx with a shallower energy level skeleton. To gain more insights into hole transfer characteristics at the perovskite/HTL interface, TRPL was performed, as shown in FIG. 2G. The experimental TRPL data are fitted with a bi-exponential decay function to yield the fast decay part (lifetime τ₁) and the slow decay part (lifetime τ₂) as listed in Table 1. The τ₁ is ascribed to the fluorescence quenching due to interfacial charge transfer at the perovskite/HTL interface, and τ₂ is mainly determined by the defect state-related bulk charge recombination in perovskite films. The bare perovskite film generated a long PL decay lifetime τₐᵥₑ of 788.51 ns, showing the high crystallization quality of perovskite film. P3HT HTL effectively accelerated PL decay (τₐᵥₑ of 71.55 ns) through efficient and fast accepting holes from perovskite. Compared with the perovskite film with P3HT HTL, the P3HT/NiOₓ stack film shows smaller τₐᵥₑ of 45.86 ns, which again confirms the conclusion that P3HT/NiOx bilayer can help hole collection based on a cascade type-II energy level alignment. The smallest τₐᵥₑ of 19.18 ns was noted for the perovskite film with P3HT/NiOₓ-CTAB HTL, corresponding to the most quenched steady state PL intensity in FIG. 2F. Therefore, the addition of NiOx-CTAB on P3HT not only provides protection to the perovskite underneath, but also promotes the most efficient holes collection at the perovskite/HTL interface, indicating a promising application in perovskite solar cells with carbon electrode.

TABLE 1

| Samples | A₁ | τ₁(ns) | A₂ | τ₂(ns) | τₐᵥₑ(ns) |
|---|---|---|---|---|---|
| Perovskite | 0.31 | 101.47 | 0.60 | 831.82 | 788.51 |
| Perovskite/P3HT | 0.22 | 15.51 | 0.59 | 75.82 | 71.55 |
| Perovskite/P3HT/NiOₓ | 0.34 | 5.04 | 0.38 | 49.57 | 45.86 |
| Perovskite/P3HT/NiOₓ-CTAB | 0.54 | 3.51 | 0.32 | 23.19 | 19.18 |

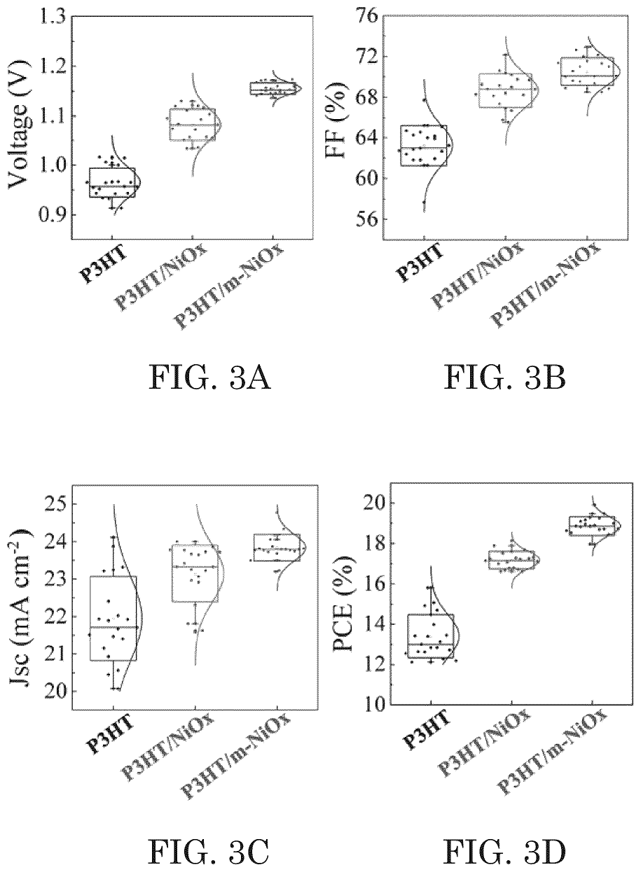

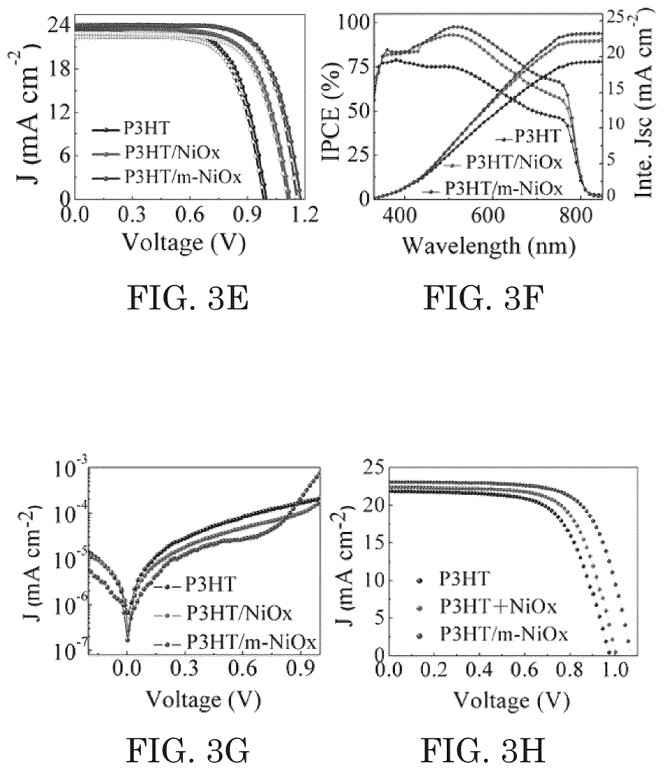

Solar cells were fabricated using the various HTLs. The fabrication was carried out with the blade-coating method in ambient air, which is the commercial process and has scalability and feasibility. Statistical performance was collected for each case from 20 repeatable solar cells (FIG. 3A-D). The control devices (perovskite/P3HT) have an average V_{oc} of 0.96 V, a J_{sc} of 21.8 mA cm⁻², a fill factor (FF) of 63.2%, and a PCE of 13.3%. In comparison, the devices with P3HT/NiOₓ HTL present an enhanced average photoelectric conversion efficiency (PCE) of 17.18%. The solar cells with P3HT/NiOₓ-CTAB HTL exhibit the highest average PCE of 18.8%, with an improved average V_{oc} of 1.15 V, J_{sc} of 23.8 mA cm⁻², and FF of 69%. The J-V curves from the best devices, including both the reverse and forward scans, are shown in FIG. 3E. Compared with the control device with a PCE of 15.8%, the solar cells with P3HT/NiOx generate a higher PCE of 18.1% while P3HT/NiOx-CTAB cells deliver the highest efficiency of 20.2%; this is the state-of-the-art value among ambient air blade-coated perovskite solar cells with a blade-coated carbon electrode. The hysteresis index [HI=((PCE_{RS}−PCE_{FS})/PCE_{RS}] of the solar cells decreased from 3.5% for P3HT HTL device to 2.1% for P3HT/NiOx sample and further to the smallest 1.6% for the P3HT/NiOx-CTAB one, suggesting the preferential electrical tolerance of P3HT/NiOx -CTAB protected solar cells. FIG. 3F presents the measured incident photocurrent conversion efficiency (IPCE) curves and the corresponding integrated current values (Jᵢₙ). It was found that the External Quantum Efficiency (EQE)-derived Jᵢₙ was 23.30 mA·cm⁻², 22.27 mA·cm⁻² and 19.41 mA·cm⁻² for perovskite solar cells with P3HT/NiOx-CTAB, P3HT/NiOx, and bare P3HT HTLs, respectively, consistent with the J-V measurement.

To investigate the rectification performance of the three photovoltaic structures, the dark J-V plots of solar cells with different HTLs were characterized, as shown in FIG. 3G. It shows that the HT bilayer enables relatively better electrical rectification by reducing the dark current of devices at low bias voltages compared to the bare P3HT HTL. Efficient charge separation and transfer collection at the optimized perovskite/P3HT/NiOx-CTAB interface allow for this good rectification performance, as demonstrated from energy level alignment and the PL results. The preferential I-V properties of target devices in dark partly benefit the better photovoltaic performance of the solar cells.

To further study the advantage of the P3HT/NiOx HT bilayer, reference devices with P3HT and NiOx blended (P3HT+NiOx) single layer HTL were made. As shown in FIG. 3H, the devices with P3HT+NiOₓ single layer HTL had a maximum PCE of 15.18%, higher than the devices based on bare P3HT HTL (13.85%). However, the P3HT/NiOₓ HT bilayer delivered the most efficient performance with an efficiency of 17.06%, meaning that the bilayer structure is superior as HTL for carbon-based perovskite solar cells.

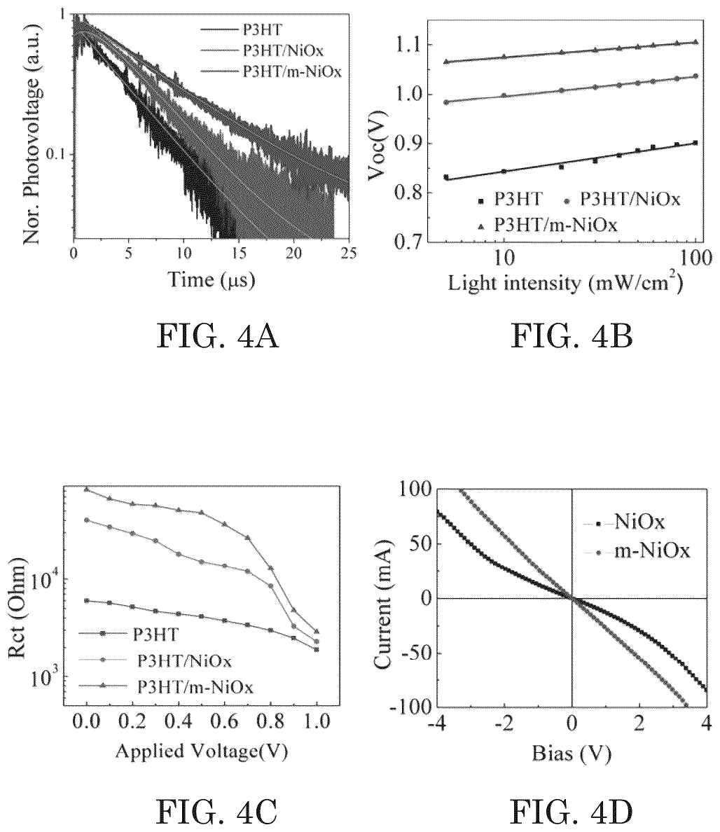

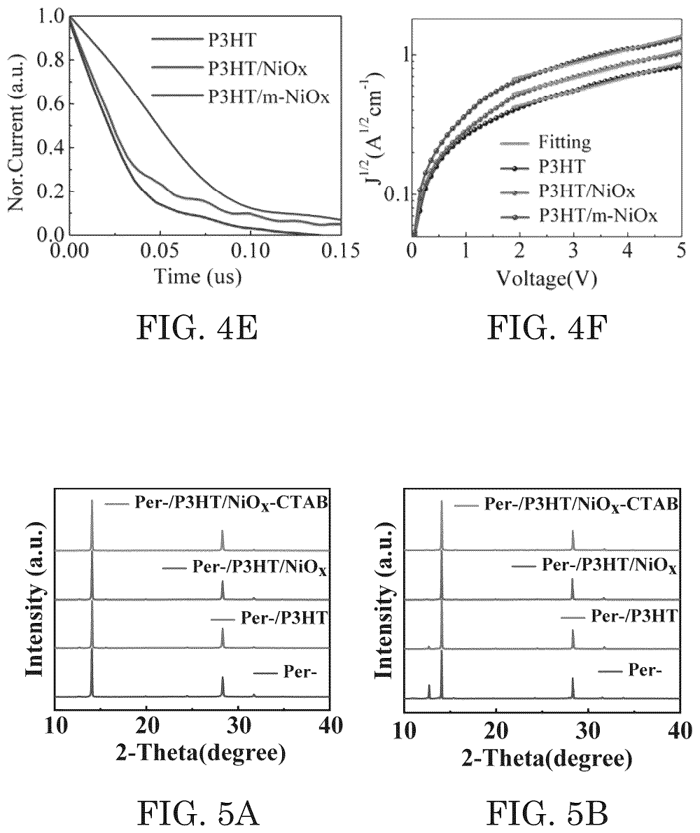

To fully understand the reason for the improved efficiency after adoption of NiOx and CTAB modification, corresponding optoelectronic analysis was carried out on the devices with different HTLs. Mainly, the analysis focused on charge dynamics relating to transfer, collection and recombination at the perovskite/HTL interface. Typically, transient photovoltage (TPV) measurement is a precise technique to study the charge recombination process in solar cells. Herein, the TPV results of the three cells are given in FIG. 4A. As is seen, the cells with P3HT, P3HT/NiOx, and P3HT/NiOx-CTAB shows a decay lifetime of 4.7 microseconds, 5.6 microseconds and 8.2 microseconds, respectively. A slower photovoltage decay process indicates depressed charge nonradiative recombination loss due to lower charge defect density in perovskite film or back transfer recombination at interfaces. The adoption of different HTLs would not influence the crystallization of perovskite (defect density), it is the quality of interface alignment that accounts for photovoltage decay process. From the PL and charge rectification results, it is inferred that compared to the bare P3HT HTL, the cascade P3HT/NiOx (NiOx-CTAB) interface inhibits charge back transfer recombination and thus elongates photovoltage decay.

The above conclusion is further confirmed by the other characterizations on charge dynamics, such as light intensity dependence of V_{oc} and electrochemical impedance spectra (EIS). A linear semi-logarithmic curves was obtained by plotting V_{oc} versus logarithm light intensity with a slope of nkT/q (FIG. 4B), where n is the ideality factor, k is the Boltzmann constant, T is the absolute temperature, and q is the elementary charge. The calculated n factors of the control (P3HT) and target (P3HT/NiOₓ and P3HT/NiOx-CTAB) devices were 2.26, 1.59 and 1.20 for corresponding solar cells with P3HT, P3HT/NiOx and P3HT/NiOx-CTAB as HTL, respectively. According to previous reports, the slope reflects charge recombination loss in solar cells, which indicates that the adoption of NiOx, especially NiOx-CTAB, behaves better in inhibiting charge recombination in solar cells. Meanwhile, the electrochemical impedance spectra (EIS) measurements under different bias voltages (from 0 V to 1.0 V with frequencies ranging from 1M HZ to 1000 HZ) directly give the charge transfer recombination resistance (Rct) at the interfaces of the solar cells (FIG. 4C). The Rct value, extracted from the diameter of a semicircle in Nyquist plot near open circuit voltage, is enlarged from 1750 Ω for P3HT HTL device to 2235 and 3546 Ω for P3HT/NiOx and PEHT/NiOx-CTAB devices, which apparently reflects the benefit of modified double layer HTLs in blocking charge recombination at the interfaces.

Compared to NiOx, the CTAB doped NiOx exhibits a shallower VB level that is closer to the work function of carbon electrode (FIG. 2E). To clarify the influence of this variation on interfacial electrical contact, we measured the I-V properties of metal-semiconductor contact (ITO/NiOx or m-NiOx/C). The modified NiOx enables a linear IV response compared with a slight rectifying effect of the bare NiOx (FIG. 4D). As the ITO and carbon have similar work function, this I-V result indicates that the NiOx-CTAB/electrode enables a near ohmic contact that is beneficial to holes extraction and collection at the anode. The facilitated charge extraction in solar cells is further confirmed by transient photocurrent study in FIG. 4E. A photocurrent decay lifetime of 61.7 nanoseconds, 34.6 nanoseconds, and 30.2 nanoseconds is obtained for the devices with P3HT, P3HT/NiOx, and P3HT/NiOx-CTAB HTL, respectively. NiOx-CTAB exhibited a faster decay than P3HT and P3HT/NiOx, indicating a better interfacial charge extraction capability in this cell. The hole mobilities in hole-only devices were researched by space charge-limited current (SCLC) method, where the carrier mobility can be calculated from the Mott-Gurney formula (J_{D}=9μεᵣε₀V²/8L³). As shown in FIG. 4D, the hole mobility of NiOx-CTAB (3.09×10⁻³ εᵣ⁻¹ cm² V⁻¹ s⁻¹) device is higher than that of P3HT/NiOx (2.93×10⁻³ εᵣ⁻¹ cm² V⁻¹ s⁻¹) and bare P3HT (2.85×10⁻³ εᵣ⁻¹ cm² V⁻¹ s⁻¹) devices, suggesting that P3HT/NiOx-CTAB double layer has preferential advantage as a high-quality HTL to improve the hole transport over interfaces.

Besides the improved charge kinetics that alleviate the conversion efficiency of solar cells with modified HTLs, compared to the bare perovskite and perovskite covered with only P3HT samples, enhanced surface protection ability of the composite P3HT/NiOx films was suggested according to the results in FIG. 1. To directly evaluate this effect, the XRD patterns of the original perovskite films with different surface coverage and those after being stored under the ambient conditions for 15 days were measured as shown in FIGS. 5A and B. It can be seen that the hydrophobic P3HT molecular layer coverage could greatly depress the decomposition (appearance of PbI₂ byproduct) of perovskite stored for 15 days in ambient air (humidity 40-60%, temperature 27-30° C.). In comparison, the perovskite films with P3HT/NiOx-CTAB maintained the full diffraction peaks with the same crystallinity as the fresh samples.

While example embodiments have been described in connection with what is presently considered to be an example of a possible most practical and/or suitable embodiment, it is to be understood that the descriptions are not to be limited to the disclosed embodiments, but on the contrary, is intended to cover various modifications and equivalent arrangements included within the spirit and scope of the example embodiment. Those skilled in the art will recognize or be able to ascertain using no more than routine experimentation, many equivalents to the specific example embodiments specifically described herein. Such equivalents are intended to be encompassed in the scope of the claims, if appended hereto or subsequently filed.

1. A solar cell comprising: a glass substrate or a plastic polymeric substrate; a first electrode disposed on the glass substrate or the plastic polymeric substrate; an electron transport layer disposed on the first electrode; a perovskite layer disposed on the electron transport layer; an organic-inorganic hole transport bilayer comprising an organic layer which is disposed on the perovskite layer and an inorganic layer which is disposed on the organic layer; and a second electrode disposed on the inorganic layer.

2. The solar cell of claim 1, wherein the organic layer of the organic-inorganic hole transport bilayer comprises one of 2,2′,7,7′-tetrakis(N,N-di-p-methoxyphenyl-amine)-9,9′-spirobifluorene, poly(3,4-ethylenedioxythiophene) polystyrene sulfonate, poly[bis(4-phenyl)(2,4,6-trimethylphenyl)amine, poly(N,N′-bis(4-butylphenyl)-N,N′-bis(phenyl)benzidine, and a polythiophene.

3. The solar cell of claim 2, wherein the inorganic layer of the organic-inorganic hole transport bilayer comprises one of CuX (X═I or S), CuXCN (X═S or Se), MxOy (M═Ni, Mo, V, Co, or Cu), and CuMO₂ (M═Ga, Cr, or Al).

4. The solar cell of claim 3, wherein the organic layer is a polythiophene layer.

5. The solar cell of claim 4, wherein the inorganic layer is a nickel oxide layer.

6. The solar cell of claim 5, wherein the nickel oxide is a nickel oxide-alkyl ammonium bromide layer.

7. The solar cell of claim 6, wherein nickel oxide-alkyl ammonium bromide layer is a nickel oxide-cetyltrimethylammonium bromide nanoparticle layer.

8. The solar cell of claim 7, wherein perovskite layer comprises FA_{0.6}MA_{0.4}PbI₃.

9. The solar cell of claim 8, wherein the FA_{0.6}MA_{0.4}PbI₃ of the perovskite layer is doped with guanidinium chloride.

10. The solar cell of claim 9, wherein the electron transport layer is a SnO₂ layer.

11. The solar cell of claim 10, wherein the substrate is a glass substrate.

12. The solar cell of claim 10, wherein the substrate is a plastic polymeric substrate.

13. The solar cell of claim 12, wherein the first electrode is an indium tin oxide electrode.

14. A method of fabricating a solar cell, the method comprising: selecting a substrate and first electrode combination, the substrate and first electrode combination comprising one of an indium tin oxide electrode and glass combination or an indium tin oxide electrode and plastic polymeric combination; annealing an electron transport layer onto the indium tin oxide electrode; coating the electron transport layer with a perovskite solution to provide a perovskite layer; annealing the perovskite layer to the electron transport layer; coating the perovskite layer with an organic hole transfer layer; coating the organic hole transfer layer with an inorganic hole transfer layer to provide an organic-inorganic hole transfer bilayer; and coating the inorganic hole transfer layer of the organic-inorganic hole transfer bilayer with a carbon electrode, thereby fabricating the solar cell.

15. The method of claim 14, further comprising dissolving guanidinium chloride into the perovskite solution before coating the electron transport layer with the perovskite solution.

16. The method of claim 15, wherein the inorganic hole transport layer is synthesized with nickel oxide.

17. The method of claim 16, further comprising mixing the nickel oxide with cetyltrimethylammonium bromide prior to synthesize the inorganic hole transport layer.

18. The method of claim 17, wherein the perovskite solution comprises FA_{0.6}MA_{0.4}PbI₃.

19. The method of claim 18, wherein the organic hole transport layer is synthesized with a polythiophene.
